(19) United States
(12) Patent Application Publication
(10) Pub. No.: US 2015/0200270 A1
(43) Pub. Date: Jul. 16, 2015

(54) FIELD EFFECT TRANSISTORS FOR HIGH-PERFORMANCE AND LOW-POWER APPLICATIONS

(71) Applicant: GLOBALFOUNDRIES Inc., Grand Cayman (KY)

(72) Inventors: Stefan Flachowsky, Dresden (DE); Hermann Sachse, Dresden (DE); Maciej Wiatr, Dresden (DE)

(73) Assignee: GLOBALFOUNDRIES Inc., Grand Cayman (KY)

(21) Appl. No.: 14/156,861

(22) Filed: Jan. 16, 2014

(51) Int. Cl. H01L 29/66; H01L 27/092; H01L 29/78; H01L 21/8238

(52) U.S. Cl. CPC H01L 29/66537; H01L 29/665; H01L 29/66575; H01L 21/823807; H01L 27/092; H01L 29/7816

(57) ABSTRACT

When forming semiconductor devices comprising high performance or low-power field effect transistors, the threshold voltage of the transistors is adjusted by the halo implantation and the source and drain regions are defined by a single implantation step. Thus, the number of process steps is reduced, whereas the electrical characteristics, such as leakage level, and performance of the transistors are maintained compared to conventional transistors.

### BACKGROUND OF THE INVENTION

1. Field of the Invention

The present disclosure generally relates to the fabrication of integrated circuits, and, more particularly, to the fabrication of high-performance and low-power field effect transistors for low-cost CMOS devices.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry including field effect transistors, CMOS technology is currently one of the most promising approaches due to the superior characteristics in view of operating speed and/or power consumption and/or cost efficiency. During the fabrication of complex integrated circuits using, for instance, CMOS technology, millions of transistors, i.e., N-channel transistors and P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions.

In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as channel length. Hence, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length, and associated therewith the reduction of channel resistivity, is a dominant design criterion for accomplishing an increase in the operating speed of the integrated circuits.

Presently, the vast majority of integrated circuits are based on silicon due to substantially unlimited availability, the well-understood characteristics of silicon and related materials and processes and the experience gathered during the last 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows subsequent high temperature processes to be performed, as are required, for example, for anneal cycles to activate dopants and to cure crystal damage without sacrificing the electrical characteristics of the interface.

For the reasons pointed out above, in field effect transistors, silicon dioxide is preferably used as a base material of a gate insulation layer that separates the gate electrode, frequently comprised of polysilicon or metal-containing materials, from the silicon channel region. In steadily improving device performance of field effect transistors, the length of the channel region has continuously been decreased to improve switching speed and drive current capability. It turns out that decreasing the channel length requires an increased capacitive coupling between the gate electrode and the channel region and an adapted profile of the source and drain regions to avoid the so-called short channel behavior during transistor operation. The short channel behavior may lead to an increased leakage current and to a pronounced dependence of the threshold voltage on the channel length. Aggressively scaled transistor devices with a relatively low supply voltage and thus reduced threshold voltage may suffer from an exponential increase of the leakage current while also requiring enhanced capacitive coupling of the gate electrode to the channel region. Thus, the thickness of the silicon dioxide layer has to be correspondingly decreased to provide the required capacitance between the gate and the channel region. For example, a channel length of approximately 80 nm may require a gate dielectric made of silicon dioxide as thin as approximately 1.2 nm. Although, generally, usage of high speed transistor elements having an extremely short channel may substantially be restricted to high speed signal paths, whereas transistor elements with a longer channel may be used for less critical signal paths, the relatively high leakage current caused by direct tunneling of charge carriers through an ultra-thin silicon dioxide gate insulation layer may reach values for an oxide thickness in the range of 1-2 nm that may not be compatible with thermal power design requirements for performance-driven circuits.

Therefore, replacing silicon dioxide based dielectrics, at least in part, as the material for gate insulation layers has been considered, particularly for extremely thin silicon dioxide based gate layers. Possible alternative materials include materials that exhibit a significantly higher permittivity so that a physically greater thickness of a correspondingly formed gate insulation layer provides a capacitive coupling that would otherwise be obtained by an extremely thin silicon dioxide layer.

Additionally, transistor performance may be increased by providing an appropriate conductive material for the gate electrode so as to replace the usually used polysilicon material, at least in the vicinity of the gate dielectric material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides enhanced capacitance based on the same thickness as a silicon dioxide based layer, while additionally maintaining leakage currents at an acceptable level. On the other hand, a non-polysilicon material, such as titanium nitride and the like, in combination with other metals, may be formed so as to connect to the high dielectric material, thereby substantially avoiding the presence of a depletion zone and providing superior conductivity compared to the doped polysilicon material.

Since the threshold voltage of the transistors, which represents the voltage at which a conductive channel forms in the channel region, is significantly determined by the work function of the gate material, such as the polysilicon or the metal-containing gate material, and of the work function of the silicon of the channel region, an appropriate adjustment of the effective work functions with respect to the conductivity type of the transistor under consideration and the performance characteristics thereof has to be guaranteed. Therefore, an appropriate metal-containing gate material has to be employed or an appropriate dopant species has to be incorporated into the polysilicon region of the gate electrode. Furthermore, typically, an appropriate dopant species has to be incorporated into the channel region of the transistor. In particular in CMOS devices comprising transistors with different threshold voltages, the transistors typically comprise differently doped channel regions formed by corresponding threshold voltage well implantations.

As mentioned above, a reduction of the channel length in modern devices leads to an improved conductivity. However, in some cases, it may be desirable to further improve the conductivity by enhancing carrier mobility in the channel region without excessively decreasing the channel length. Accordingly, in modern devices, a so-called retrograde channel doping profile is contemplated. As is well known, dopant atoms in the semiconductor lattice may represent scattering centers for charge carriers moving under the influence of an electrical field prevailing in the semiconductor region. Therefore, in modern devices, the retrograde channel dopant profile may be used, that is, the concentration of dopants increases from the gate insulation layer to the areas located deeper down the channel region, so that charge carriers forming the conductive channel essentially in the vicinity of the gate insulation layer encounter a relative low concentration of scattering centers so that the overall conductivity in the channel is enhanced. A retrograde channel dopant profile, however, is difficult to obtain due to inevitable diffusion effects.

Furthermore, any channel implantation increases lattice damage in the channel region. Forming a gate insulation layer of a few nanometers in thickness, as described above, requires an advanced process technology to minimize any lattice damage in the semiconductor region underlying the gate insulation layer so as to allow formation of a high quality gate insulation layer, such as an oxide layer, for guaranteeing a high degree of reliability of the device over the whole operating life. Moreover, only a relatively intact semiconductor region allows the formation of a gate insulation layer having a relatively smooth interface with the semiconductor material so that scattering events of charge carriers are minimized.

Although the reduction of the gate length is beneficial for obtaining smaller and faster transistor elements, it turns out, however, that a plurality of issues are additionally involved to maintain proper transistor performance for a reduced gate length. One challenging task in this respect is the provision of appropriate shallow junction regions, i.e., source and drain regions, which nevertheless exhibit a high conductivity so as to minimize the resistivity in conducting charge carriers from the channel to a respective contact area of the drain and source regions. The requirement for shallow junctions having a high conductivity is commonly met by performing an ion implantation sequence so as to obtain a high dopant concentration having a profile that varies laterally and vertically, i.e., in the depth direction.

Generally, the ion implantation process is a viable technique for introducing certain dopant species, such as P-type dopants, N-type dopants and the like, into specified device areas, which are usually defined by appropriate implantation masks, such as resist masks and the like. During the definition of active transistor regions, such as P-wells and N-wells, and during the formation of the actual drain and source dopant profiles, respective resist masks are typically provided to selectively expose and cover the device areas so as to introduce the required type of dopant species. That is, the respective implant species is introduced into non-covered device portions while the resist material blocks the dopant species and prevents dopant penetration into covered device portions, wherein the average penetration depth is determined by the implantation energy for a given implant species and a given material composition of the device area, while the dopant concentration is determined by the implantation dose and the implantation duration. Thereafter, the resist mask is removed and a further implantation process may be performed according to device requirements, e.g., for transistors with different threshold voltages on the basis of a newly formed resist mask. Hence, a plurality of implantation processes are to be performed during the formation of transistor elements. In particular, the demand for shallow junctions, i.e., source and drain dopant profiles, in particular in portions located in the vicinity of the channel region, which are also referred to as source and drain extensions, requires moderately low implantation energies at high doses. Thus, the dopants are located in a thin surface layer of the resist mask, which may impede the resist removal process and consequently increase the loss of material in the exposed regions so that the devices to be formed may be adversely affected, in particular devices requiring a high number of implantation and mask steps.

A corresponding manufacturing process for field effect transistors of a conventional CMOS element will be detailed in the following by referring to FIGS. 1a-1h. FIG. 1a shows a schematic cross-sectional view of a semiconductor element 100 at an early manufacturing stage. The semiconductor element 100 is illustrated in this example as a complementary MOS transistor pair, wherein, in a semiconductor layer 102 of a substrate 101, such as a silicon layer, a shallow trench isolation 103, for example comprising silicon dioxide, is formed to define active regions 102a, 102b. Generally, an active region is to be understood as a semiconductor region of the layer 102 in and above which one or more transistors are to be formed. In FIG. 1a, the active region 102b represents the active region of an N-channel transistor, and the active region 102a represents the active region of a P-channel transistor. A P-well structure 120b formed in the active region 102b may comprise P-type dopants such as boron. The active region 102a is covered by a mask 104a, such as a resist mask.

A typical process flow for forming the semiconductor device 100 shown in FIG. 1a may comprise the following steps. First, the shallow trench isolation 103 is formed by photolithography, etching and deposition techniques that are well known in the art. Thereafter, the P-well structure 120b is typically defined by a plurality of sequentially performed ion implantation processes 105a, commonly known as buried implants, fill implants, punch-through implants and Vₜₕ implants, wherein Vₜₕ indicates the threshold voltage of the transistor elements to be formed. Prior to the actual implantation process, a sacrificial layer, such as an oxide layer (not shown), may be deposited over the semiconductor region 102b to more precisely control the implantation process. During implantation, the dose and the energy of the respective implantation process is controlled so as to locate the peak concentration of the corresponding ion species in the appropriate depth.

FIG. 1b schematically illustrates the device 100 in a further advanced process stage in which the resist mask 104a (FIG. 1a) is removed from the active region 102a and a resist mask 104b is formed above the active region 102b. An N-well structure 120a formed in the active region 102a may comprise N-type dopants, such as phosphorus and arsenic, incorporated by the implantation process 105b. It should be noted that, due to the nature of the implantation processes 105a (FIG. 1a) and 105b, the boundaries of the implantation regions for defining the N-well structure 120a and the P-well structure 120b are not sharp boundaries as shown in FIGS. 1a and 1b but, instead, have gradual transitions.

FIG. 1c schematically illustrates a cross-sectional view of the semiconductor device 100 in a manufacturing stage in which gate electrode structures 130a, 130b may be provided with lateral dimensions of, for instance, 50 nm and less. The gate electrode structure 130a may represent a gate electrode structure of a P-channel transistor to be formed in and above the active region 102a while the gate electrode structure 130b may represent a gate electrode structure of an N-channel transistor to be formed in and above the active region 102b.

In the manufacturing stage shown, the gate electrode structures 130a, 130b comprise a gate dielectric material 133a, 133b, which may comprise silicon oxide, silicon oxynitride and/or high-k dielectric materials, such as hafnium oxide, hafnium silicate, zirconium oxide and the like. The high-k dielectric materials may be implemented so as to provide a total dielectric constant that is 10.0 and higher. Furthermore, a metal-containing electrode material (not shown), such as titanium nitride and the like, is typically provided in combination with the high-k dielectric material in order to obtain the required threshold voltage characteristics and the like. It should be noted, however, that the materials in the gate electrode structure 130a on the one hand, and in the gate electrode structure 130b on the other hand, may differ in their material composition, for instance with respect to a work function metal species, since typically different work functions are required for the gate electrode structures of transistors of different conductivity type. The gate electrode structures 130a, 130b comprise an electrode material 131a, 131b, such as a silicon-based electrode material or a metal-based electrode material. The silicon-based electrode material may be provided in combination with a dielectric cap layer (not shown) or cap layer system, for instance comprising silicon nitride, silicon dioxide and the like.

Furthermore, spacer structures 134a, 134b, for instance comprised of one or more silicon nitride and/or silicon oxide layers and the like, are formed on sidewalls of the electrode materials 131a, 131b and the sensitive materials 133a, 133b of the gate electrode structures 130a, 130b.

The device 100 as shown in FIG. 1c may be formed on the basis of the following process steps. The gate electrode structures 130a, 130b are typically formed on the basis of complex deposition and patterning processes in order to provide the gate materials for the various transistor types. That is, in case a metal gate electrode is formed, typically different work function metal species have to be provided for transistors of different conductivity type, a corresponding deposition, masking and patterning regime is applied in this manufacturing stage. Subsequently the gate layer stack is patterned by using sophisticated lithography and etch strategies, thereby finally obtaining the gate electrode structures 130a, 130b with the desired critical dimensions, i.e., with a gate length of 50 nm and significantly less in sophisticated applications. Next, a spacer layer is deposited, followed by the etching of the spacer layer in order to obtain the spacer elements 134a, 134b of the gate electrode structures 130a, 130b. It should be appreciated that the spacer structures may be additionally used for confining sensitive gate materials, in particular when high-k materials are used, and may also act as offset spacer elements for appropriately defining the lateral dopant profiles in the active regions 102a, 102b in further advanced manufacturing stages.

At the manufacturing stage depicted in FIG. 1d, the active region 102a is covered by a resist mask 107a and an implantation sequence 106a is performed that may comprise a pre-amorphization, a source and drain extension implantation, extra diffusion engineering implantations and halo implantations to define source and drain extension regions 125b and halo regions 128b in the active region 102b. The halo regions 128b may be provided with a dopant profile appropriate for reducing the short channel effects and further adjusting, in combination with the previously performed Vₜₕ implants (FIG. 1a), the desired threshold voltage of the transistor to be formed in and above the active region 102b.

FIG. 1e schematically illustrates the device 100 in a further advanced process stage in which the resist mask 107a (FIG. 1d) is removed from the active region 102a. A resist strip process is performed in order to remove the resist mask 107a, wherein the removal process may be configured as a plasma process based on, e.g., oxygen and a further reactive component, such as fluorine in the form of carbon hexa fluoride.

A further resist mask 107b is formed covering the active region 102b and exposing the active region 102a during a further high-dose implantation sequence 106b performed to provide an appropriate dopant profile in the active region 102a, representing a transistor of a different conductivity type, such as a P-channel transistor. The implantation sequence 106b that may again comprise a pre-amorphization, a source and drain extension implantation, extra diffusion engineering implantations and one or more halo implantation steps to define source and drain extension regions 125a and halo regions 128a in the active region 102a is performed. The halo regions 128a may be provided with a dopant profile appropriate for further adjusting, in combination with the previously performed implants (FIG. 1b), the desired different threshold voltage of the transistor to be formed in and above the active region 102a.

FIG. 1f schematically illustrates the transistor device 100 in a further advanced manufacturing stage. As shown, further spacer elements 135a, 135b may be provided so as to define, in combination with the offset spacers 134a, 134b, spacer structures 136a, 136b (see FIG. 1h). The spacer structures 136a, 136b may also comprise additional individual spacer elements (not shown) depending on the respective process requirements. The spacer elements 135a, 135b may be comprised of any appropriate material, such as silicon nitride, and may have a width adapted to define deep drain and source portions 126b formed by a respective implantation process 108a. At the manufacturing stage depicted in FIG. 1f, the active region 102a is covered by a resist mask 109a and the active region 102b is exposed so that an appropriate ion species may be implanted into the gate electrode and into the areas not covered by the gate structure. For driving the deep drain and source regions towards a desired depth, the corresponding lateral diffusion may also have to be accommodated by the width of spacers 135a, 135b. Thus, the overall width of the spacer structures 136a, 136b may be correlated with the overall configuration of the drain and source regions 127a, 127b (FIG. 1h) comprising the extension region 125a, 125b and the deep drain and source region 126a (FIG. 1g), 126b, wherein also the width of the spacers 135a, 135b and the thickness of the spacers 134a, 134b may be correlated in order to obtain a desired effective channel length and an appropriate dopant profile for the desired performance characteristics after an appropriate anneal process to be performed in a subsequent manufacturing stage.

FIG. 1g schematically illustrates the transistor device 100 in a further advanced manufacturing stage in which the resist mask 109a (FIG. 10 is removed from the active regions 102a. As shown, to define deep drain and source portions 126a, a respective implantation process 108b is performed. At the manufacturing stage depicted in FIG. 1g, the active region 102b is covered by a resist mask 109b and the active region 102a is exposed so that an appropriate ion species of the opposite conductivity type may be implanted into the gate electrode and into the areas not covered by the gate structure 130a.

FIG. 1h schematically illustrates the transistor device 100 in a further advanced manufacturing stage in which the resist mask 109b (FIG. 1g) is removed from the active regions 102b. As shown, a corresponding anneal process 111 may be performed at this manufacturing stage, wherein respective process parameters, that is, the effective anneal temperature and the duration of the process, may be selected such that desired lateral and vertical profiles of the drain and source regions 127a, 127b are obtained. Subsequently, silicide regions and contact elements may be formed to accomplish the manufacturing process of the transistors of the CMOS device.

In view of the above-described situation, a need exists for facilitating the manufacturing process of CMOS transistors to provide high-performance and low-power field effect transistors for low-cost CMOS devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides manufacturing techniques for reducing the number of process steps for manufacturing high-performance and low-power field effect transistors of CMOS devices. A reduced number of process steps may be achieved by modifying the source and drain implantation processes so that source and drain extension region implantation processes and deep source and drain region implantation processes for a transistor may be replaced by a single source and drain implantation. Furthermore, the halo region implantation processes may be modified so that the threshold voltage of the transistors may be adjusted without a corresponding Vₜₕ well implantation step, wherein the electrical device behavior is substantially unmodified. In particular, the transistor performance and leakage characteristic is on the same level as the performance of conventional transistors, whereas the number of process steps for manufacturing high-performance and low-power field effect transistors is reduced and consequently the duration of a typical manufacturing cycle is reduced. Thus, the throughput of an available manufacturing environment is increased, resulting in reduced manufacturing costs. Furthermore, due to the reduced number of process steps for manufacturing high-performance and low-power field effect transistors, the periods of learning and adapting cycles for introducing amended CMOS devices and consequently the “time-to-market” is also reduced.

One illustrative method of forming a semiconductor device includes providing a substrate including a semiconductor layer and forming a gate electrode structure above an active region formed in the semiconductor layer. The method further comprises performing an implantation sequence using the gate electrode structure as a mask, wherein source and drain regions and halo regions of a field effect transistor are formed, and forming silicide regions within the source and drain regions.

A further illustrative method of forming a semiconductor device includes providing a substrate including a pre-doped semiconductor layer exhibiting an initial doping concentration and forming isolation regions defining an active region in the pre-doped semiconductor layer. The method further includes performing an implantation sequence implanting source and drain regions and halo regions of a field effect transistor into the active region exhibiting the initial doping concentration.

An illustrative semiconductor device includes a substrate including a semiconductor layer and a field effect transistor formed in and above the semiconductor layer. The field effect transistor includes a gate electrode formed above the semiconductor layer and source and drain regions formed in the semiconductor layer, wherein the shape of the source and drain regions is defined by a single source and drain implantation.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1h schematically illustrate cross-sectional views of a semiconductor device during various manufacturing stages for forming source and drain regions and halo regions according to a conventional process strategy;

FIGS. 2a-2g schematically illustrate cross-sectional views of a transistor element during various manufacturing stages when performing source and drain implants and halo implants according to illustrative embodiments;

FIGS. 3a-3b schematically illustrate electrical measurement results relating to the device performance and the obtained values of the threshold voltage of a P-channel transistor according to the present invention compared to conventional P-channel transistors; and

FIGS. 4a-4g schematically illustrate cross-sectional views of an N-channel transistor and of a P-channel transistor according to further illustrative embodiments during various manufacturing stages.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

Generally, the present disclosure provides manufacturing techniques for manufacturing high-performance and low-power field effect transistors of CMOS devices, wherein the number of process steps is reduced compared to conventional manufacturing processes, whereas the transistor performance and leakage is on a comparable level. A reduced number of process steps may be achieved by modifying the source and drain implantation processes so that source and drain extension regions implantation and deep source and drain implantation processes for a transistor may be replaced by a single source and drain implantation. Furthermore, the halo implantation processes may be modified so that the threshold voltage of the transistors may be adjusted without a corresponding Vₜₕ well implantation step, wherein the electrical device behavior is substantially unmodified. In particular, the transistor performance is on the same level as the performance of conventional transistors.

The number of process steps for manufacturing high-performance and low-power field effect transistors is reduced. The reduced number of process steps may lead to an increased throughput in an available manufacturing environment.

The present disclosure should not be considered as being restricted to specific device dimensions and devices, unless such restrictions are explicitly set forth in the specification or the appended claims.

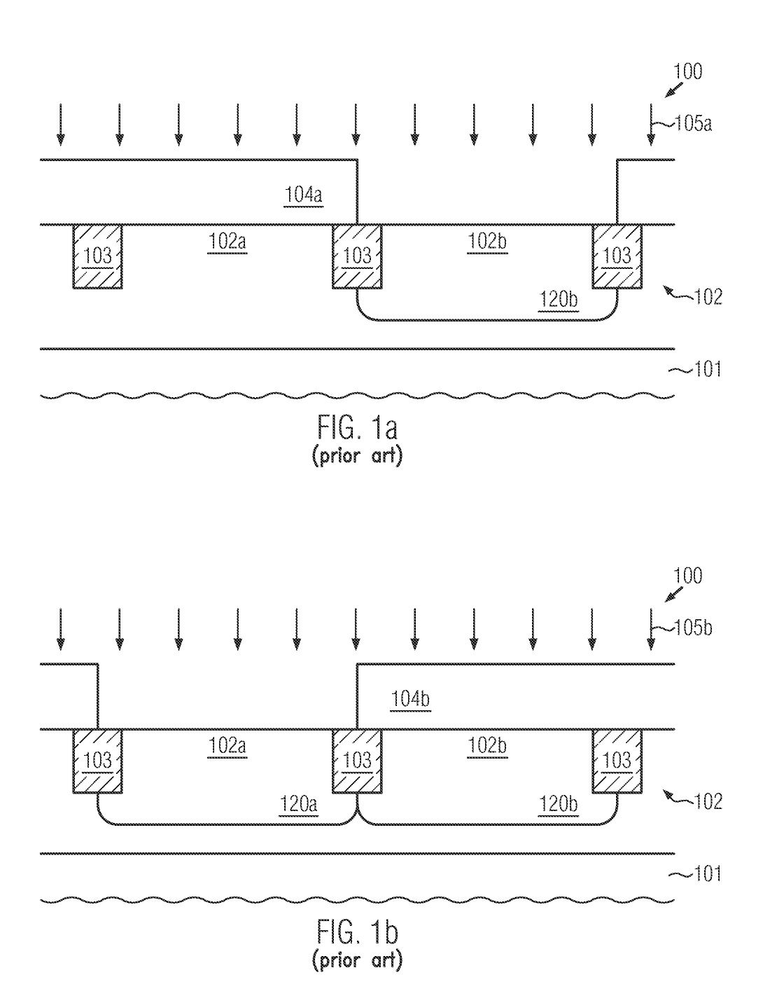

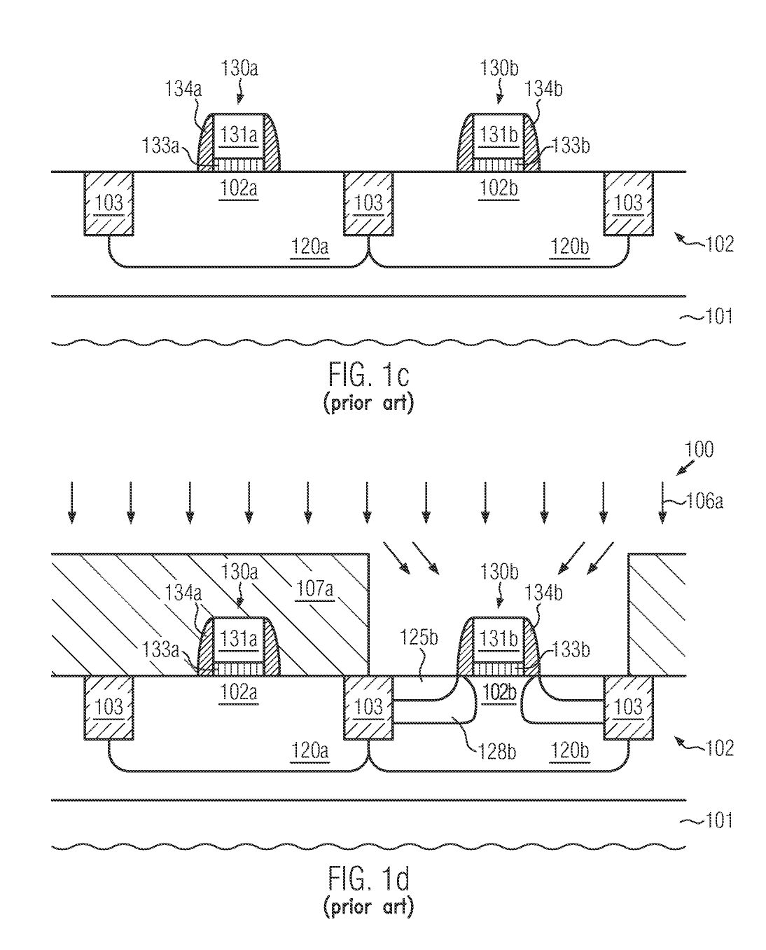

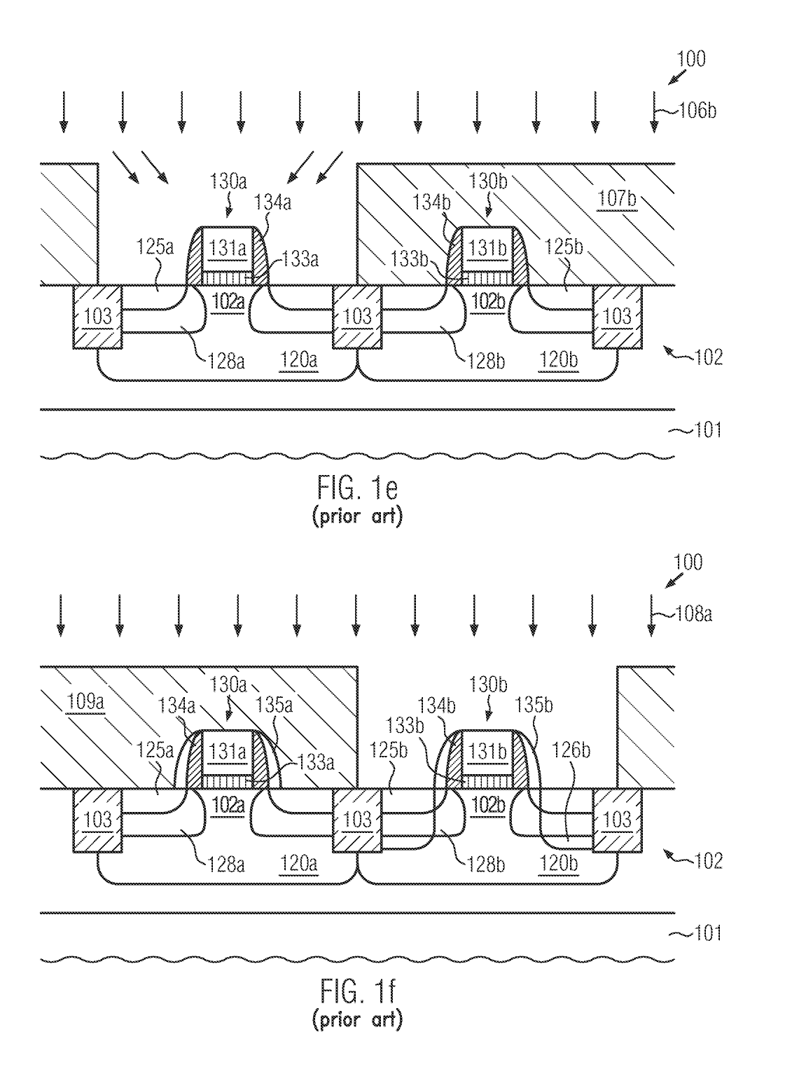

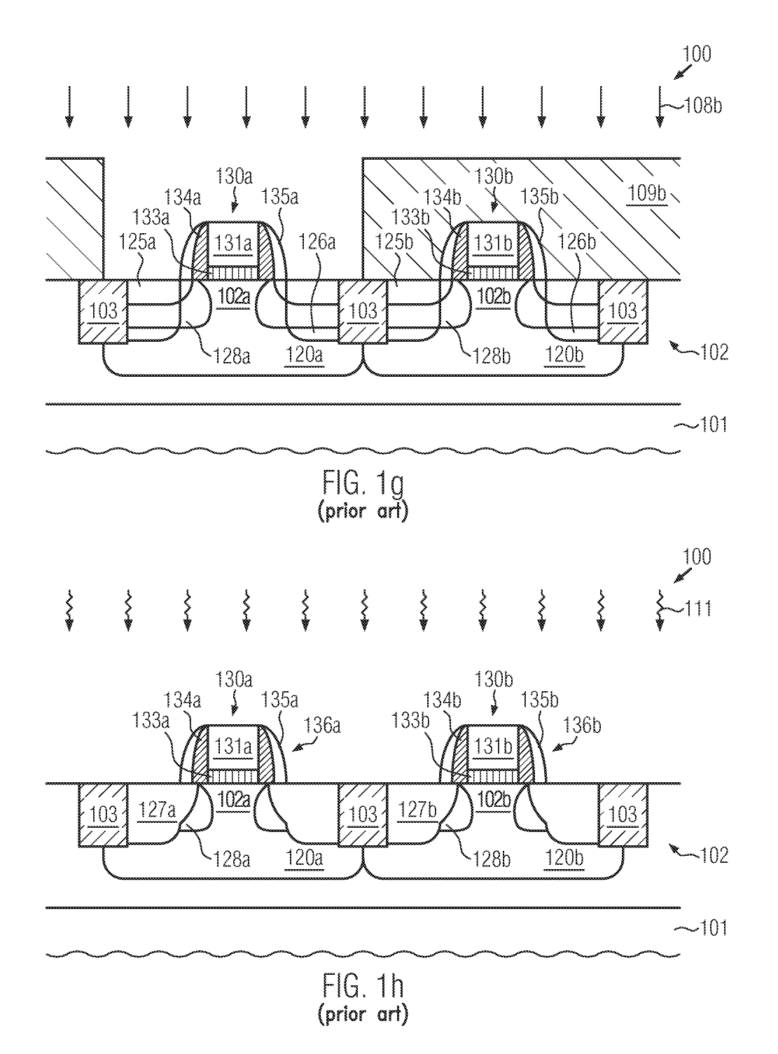

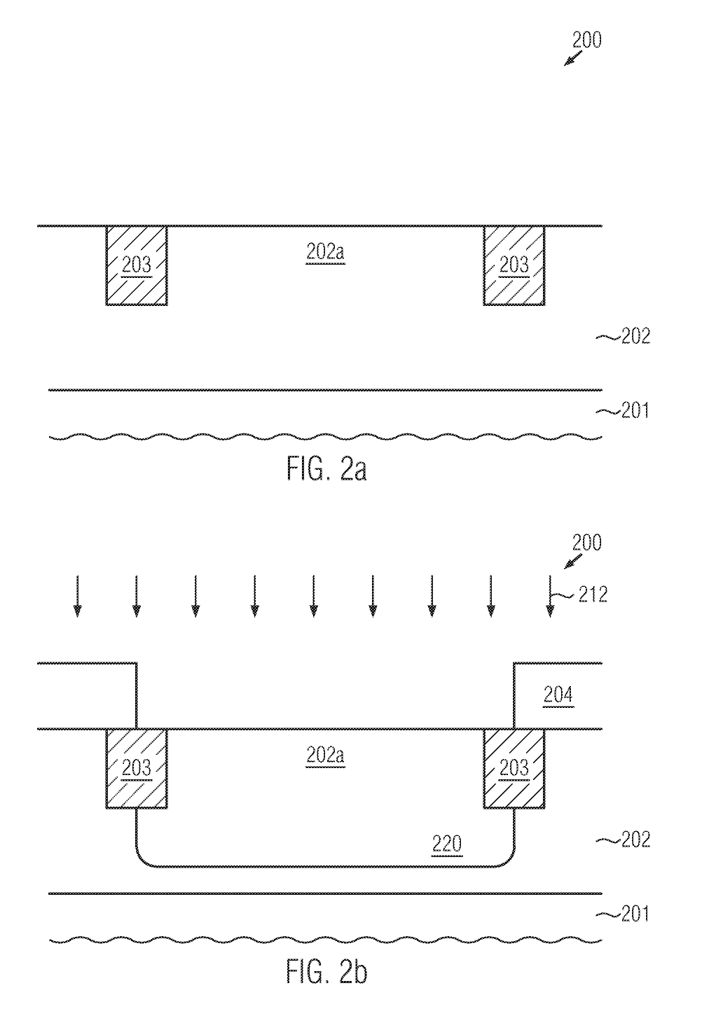

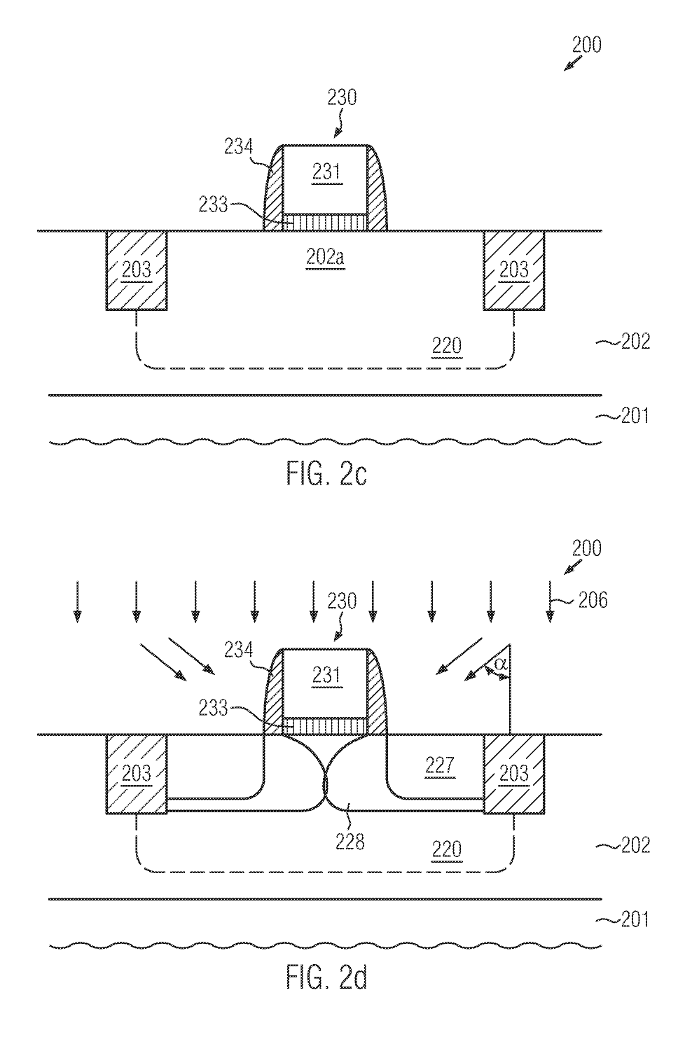

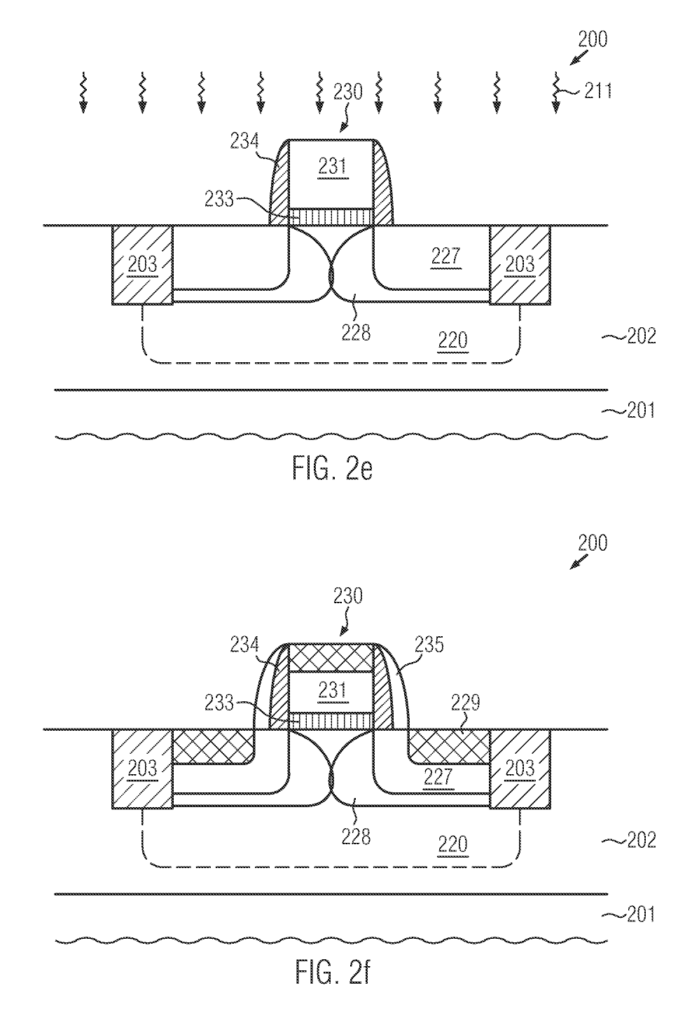

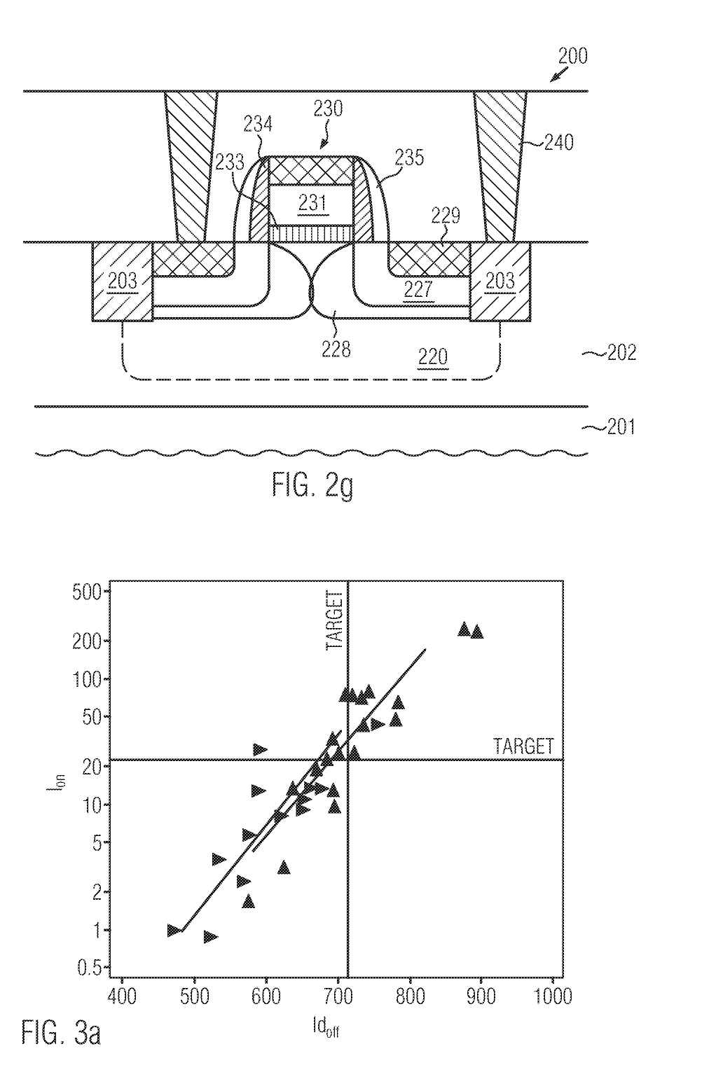

With reference to FIGS. 2a-2g, further illustrative embodiments will now be described in more detail, wherein reference may also be made to FIGS. 1a-1h, if appropriate.

FIG. 2a schematically illustrates a cross-sectional view of a semiconductor device 200 comprising a substrate 201 and a semiconductor layer 202, such as a silicon-based layer, or any other appropriate semiconductor material which may comprise a significant portion of silicon. The semiconductor layer may be pre-doped or undoped. Typically, the semiconductor layer 202 as provided by the substrate manufacturer is pre-doped and comprises a P-type dopant, such as boron, with an initial low dopant concentration as typically provided by substrate manufacturers. The semiconductor layer 202 may be formed so as to directly connect to a crystalline semiconductor material of the substrate 201 if a bulk architecture is considered, as shown in FIG. 2a, while, in other cases, an SOI (silicon-on-insulator) architecture may be provided when a buried insulation material (not shown) is formed below the semiconductor layer 202. The layer 202 may be a continuous semiconductor material in an initial state and may be divided into a plurality of active regions, such as the active region 202a, by providing appropriate isolation structures 203.

Generally, the isolation regions 203 and the active region 202a may have characteristics as already discussed above with reference to the device 100. Thus, with respect to these components and manufacturing techniques for forming, the same criteria may apply as discussed above.

FIG. 2b schematically illustrates a cross-sectional view of the semiconductor device 200 in a further advanced optional manufacturing stage. Depending on the type of transistor to be formed in the active region 202a and on the type and concentration of the pre-dopant species initially provided in the semiconductor layer 202, an isolation band implantation may be performed to ensure an appropriate electrical isolation of the transistor to be formed. In one embodiment, the semiconductor layer 202 comprises a P-type pre-dopant species and an N-type dopant species is implanted in an implantation step 212 to provide a corresponding doped region 220 which is appropriate to electrically isolate an N-channel transistor from the surrounding semiconductor material. Regions that are not intended to obtain the isolation band implantation 212 may be covered by a resist mask 204. In case, for example, a P-channel transistor is formed in the semiconductor layer 202 comprising a P-type pre-dopant species, the isolation band implantation 212 may be omitted.

FIG. 2c schematically illustrates a cross-sectional view of the semiconductor device 200 in a further advanced manufacturing stage. The doped region 220 which may be implanted to electrically isolate the transistor to be formed is indicated by a dashed line as it is an optional feature. A gate electrode 230, for instance comprised of polysilicon, pre-doped polysilicon, amorphous silicon or a metal-based electrode material 231, may be formed above the semiconductor layer 202 and may be separated therefrom by a gate insulation layer 233, which may comprise silicon oxynitride material and/or high-k material as described with regard to FIG. 1c. In this manufacturing stage, respective offset spacers 234, which may be comprised of silicon nitride, silicon dioxide, silicon oxynitride and the like, are provided with an appropriate thickness, which in turn is selected so as to define a desired offset of respective source and drain regions to be formed using the gate electrode 230 and the offset spacers 234 as an implantation mask.

It should be appreciated that the length of a channel region, i.e., the spacing between the source and drain regions in the horizontal direction, depends on the length of the gate electrode 230 and the width of the spacer 234, wherein the actual effective channel length may finally be determined by respective PN junctions formed by the source and drain regions with the channel region. That is, the effective channel length may be adjusted by a controlled diffusion process, as previously explained with regard to FIG. 1f.

The semiconductor device 200 as shown in FIG. 2c may be formed on the basis of the following well-established processes. Appropriate gate materials 231 for the gate electrode 230 and the gate insulation layer 233 may be provided, for instance, by oxidation and/or deposition for the gate insulation layer 233 and by deposition of the material 231 of the gate electrode 230, followed by advanced lithography and etch techniques in order to appropriately define the lateral dimensions of the gate electrode 230. The gate electrode 230 may be formed by a pre-doped polysilicon material by performing a corresponding implantation step prior to the gate patterning process. As a different conductivity type is required for polysilicon material of N-channel and P-channel transistors, corresponding mask techniques may be employed. For sophisticated applications, the gate length, which also affects the effective channel length, may be in the range of approximately 50 nm and even less for highly advanced semiconductor devices. Next, the offset spacer 234 may be formed on the basis of conformal deposition techniques and/or oxidation processes, followed by an etch process, wherein the initial layer thickness and the respective etch conditions may substantially determine the relevant width of the offset spacer.

FIG. 2d schematically illustrates a cross-sectional view of the semiconductor device 200 in a further advanced manufacturing stage. An implantation process 206 is performed so as to introduce the required dopant species for defining the source and drain regions 227, wherein a respective offset to the gate electrode 230 may be obtained by the offset spacers 234. A corresponding dopant species of a specified conductivity type in accordance with the design of the semiconductor device 200 is implanted. For instance, for a P-channel transistor, the source and drain regions 227 may comprise a P-type dopant species. In an illustrative embodiment, the implantation process 206 is performed to obtain source and drain regions 227 having a depth in the range of approximately 20-50 nm and a mean dopant concentration in the range of approximately 1×10²⁰ to 5×10²⁰ atoms/cm³. As source and drain dopants are also incorporated in the gate electrode, the dopant concentration in the gate electrode may be higher than the dopant concentration in the source and drain regions, when a pre-doped gate electrode material 231 is employed. Thus, a sufficient gate conductivity may be achieved even if the source and drain dopant concentration is reduced, compared to the dopant concentration of conventional transistors.

The halo regions 228 may be provided with a dopant profile appropriate for reducing the short channel effects and adjusting the desired threshold voltage of the transistor to be formed in and above the active region 202a. The halo implantation may be performed by means of a tilted implantation performed on the drain side as well as on the source side. In an illustrative embodiment, the halo implantation process 206 is performed with an inclination angle α in the range of approximately 20-60° and an implantation energy in the range of approximately 5-30 keV, wherein the applied dose may be in the range of 10¹³ to 10¹⁴ atoms/cm². In an illustrative embodiment, the process parameters of the halo implantation process 206 are chosen so that the source and the drain side halo regions form an overlap region below the gate electrode. It should be appreciated that other implantation processes may be performed, such as a pre-amorphization implantation, a diffusion engineering implantation and the like, depending on the device requirements.

FIG. 2e schematically illustrates a cross-sectional view of the semiconductor device 200 in a further advanced manufacturing stage. An anneal process 211 may be performed at this manufacturing stage, wherein respective process parameters, that is, the effective anneal temperature and the duration of the process, may be selected such that desired lateral and vertical profiles of the drain and source regions 227 are obtained as previously explained. It is to be noted that subsequently performed heat treatment, for example, during silicide formation, may entail additional diffusion effects, which may be taken into account in the anneal process 211.

FIG. 2f schematically illustrates a cross-sectional view of the semiconductor device 200 in a further advanced manufacturing stage in which silicide regions 229 are formed in the drain and source regions 227 comprising a dopant concentration defined by the drain and source implantation 206 (FIG. 2d), i.e., the drain and source dopants are implanted in the implantation sequence 206, wherein the actual dopant concentration may be obtained in the annealing step 211 (FIG. 2e) due to unavoidable diffusion effects. The drain and source regions 227 define an intermediate channel region of the transistor, which may exhibit a dopant concentration defined by the implantation step 206 (FIG. 2d) or may exhibit a pre-dopant concentration as described with reference to FIG. 2a. In one illustrative embodiment, the channel region and the drain and source regions 227 exhibit the same conductivity type. Depending on the gate electrode technique employed, a silicide region may also be formed in the gate electrode. In one illustrative embodiment, a gate replacement approach may be employed, wherein the corresponding gate electrode replacement process is performed after the formation of the silicide regions 229.

FIG. 2g schematically illustrates a cross-sectional view of the semiconductor device 200 in a further advanced manufacturing stage in which contact elements 240 may be formed to accomplish the manufacturing process of the semiconductor device 200. Subsequently, a plurality of metallization layers (not shown) may be formed, e.g., on the basis of a well-known copper damascene technique, to combine the transistor 200 with a transistor of the opposite conductivity type (not shown) to form CMOS elements and to provide the desired integrated circuit.

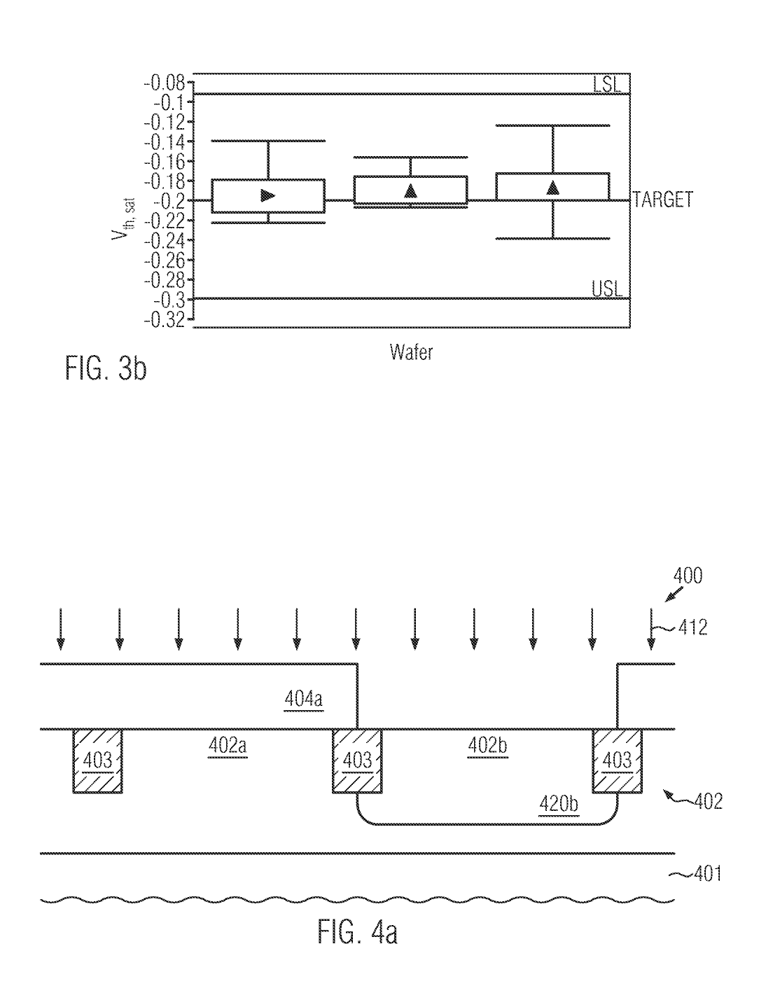

With reference to FIGS. 3a-3b, electrical measurement results obtained from P-channel transistors according to the present invention as described with reference to FIGS. 2a-2g are compared to measurement data relating to conventional P-channel transistors.

FIG. 3a illustrates a diagram of electrical measurement results relating to the device performance of a P-channel transistor according to the present invention. The electrical measurements—performed to obtain sample wafer electrical test (SWET) measurement data—indicate the performance (Iₒₙ-Id_{off}) of conventional transistors (indicated by ▴) compared to the performance (Iₒₙ-Id_{off}) of transistors manufactured according to the present invention (indicated by [symbol] ), wherein the gate length of the transistors is approximately 30 nm. In FIG. 3a, the horizontal axis represents the drain current Id_{off}. The vertical axis represents the transistor current Iₒₙ. The depicted vertical and horizontal lines indicate the target values for Id_{off} and Iₒₙ, respectively. As illustrated, the conventional P-channel transistors and the P-channel transistors according to the present invention show a comparable performance and distribution of the performance measurement values in the diagram.

FIG. 3b illustrates a diagram of SWET measurement data relating to the obtained values of the threshold voltage of P-channel transistors according to the present invention (indicated by [symbol] ) compared to values of the threshold voltage of conventional P-channel transistors (indicated by ▴). In FIG. 3b, the vertical axis represents the threshold voltage Vₜₕ. The depicted horizontal lines indicate the target value for Vₜₕ and the upper and lower limit, respectively. As illustrated, the conventional P-channel transistors as well as the P-channel transistors according to the present invention exhibit values of the threshold voltage Vₜₕ which are in a comparable range that is located sufficiently close to the target value of approximately −0.2 V and exhibit limits of variation that are clearly in the allowable range.

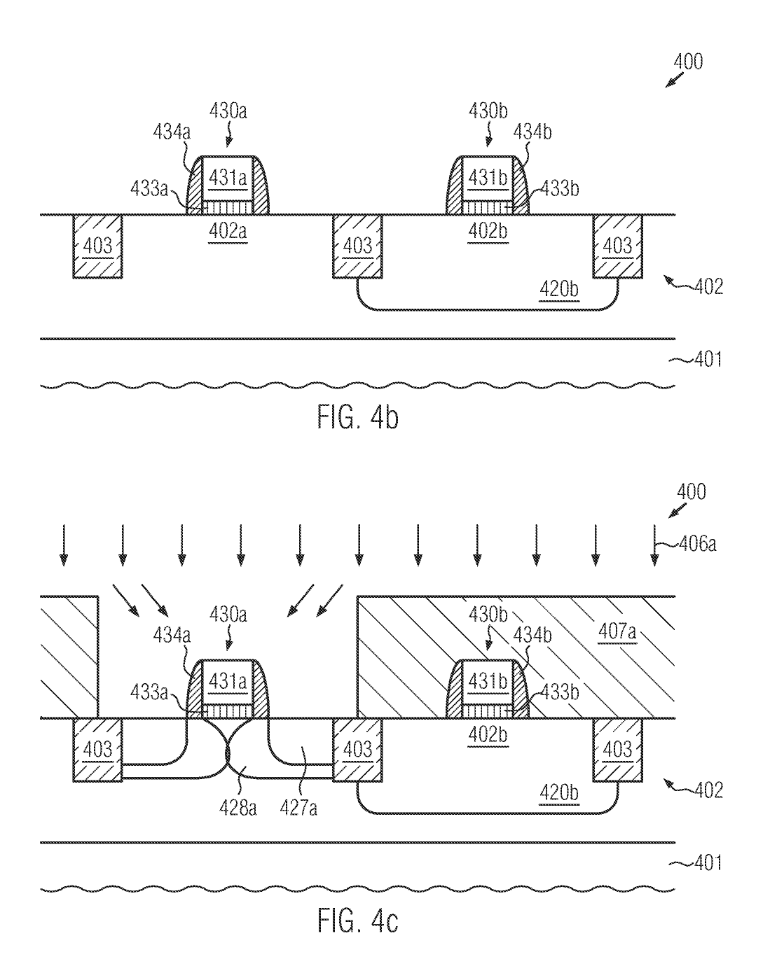

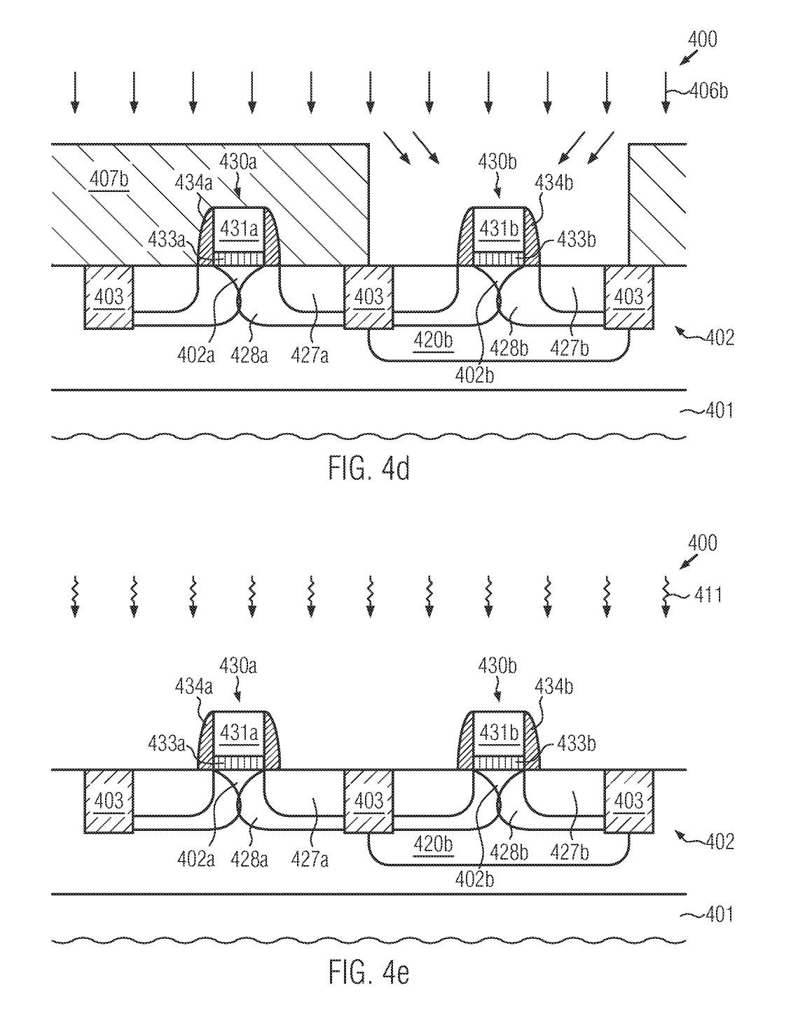

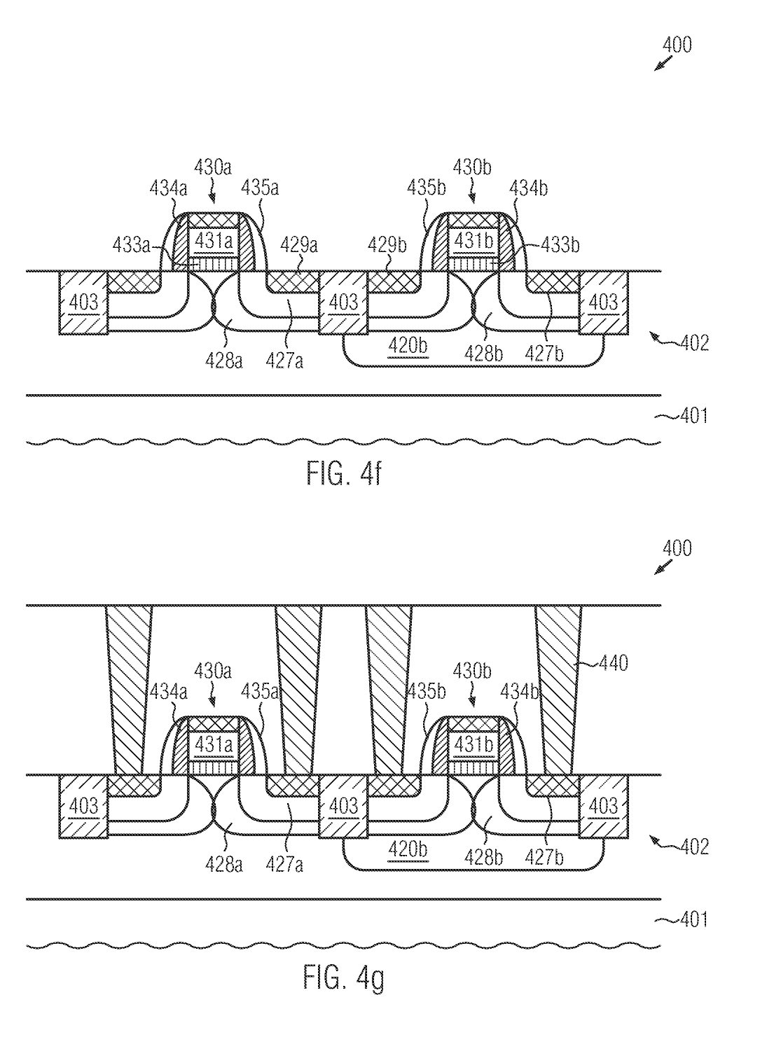

With reference to FIGS. 4a-4g, further illustrative embodiments will now be described in more detail, wherein reference may also be made to FIGS. 1a-1h and 2a-2g, if appropriate.

FIG. 4a schematically illustrates a cross-sectional view of a semiconductor device 400 comprising an N-channel transistor and a P-channel transistor according to an initial manufacturing stage. The semiconductor device 400 comprises a substrate 401 and a semiconductor layer 402, such as a silicon-based layer, or any other appropriate semiconductor material which may comprise a significant portion of silicon. The semiconductor layer 402 may be pre-doped and may comprise a P-type dopant, such as boron, with a low dopant concentration. The semiconductor layer 402 may be formed so as to directly connect to a crystalline semiconductor material of the substrate 401 if a bulk architecture is considered, while, in other cases, an SOI architecture may be provided when a buried insulation material (not shown) is formed below the semiconductor layer 402. The layer 402 may be a continuous semiconductor material in an initial state and may be divided into a plurality of active regions, such as the active regions 402a and 402b, by providing appropriate isolation structures 403, as discussed with reference to FIGS. 1a and 2a.

An isolation band implantation 412 may be performed to ensure an appropriate electrical isolation of the transistor to be formed in the active region 402b. In one embodiment, the semiconductor layer 402 comprises a P-type pre-dopant species and an N-type dopant species is implanted in the implantation step 412 to provide a corresponding N-doped region 420b which is appropriate to electrically isolate an N-channel transistor from the surrounding semiconductor material. The active region 402a which is not intended to obtain the isolation band implantation 412 is covered by a resist mask 404a. In one embodiment, a P-channel transistor is to be formed in the active region 402a and an N-channel transistor is to be formed in the active region 402b. The isolation band implantation 412 may be performed as discussed with reference to FIG. 2b.

FIG. 4b schematically illustrates a cross-sectional view of the semiconductor device 400 in a further advanced manufacturing stage in which gate electrodes 430a, 430b, for instance comprised of polysilicon, pre-doped polysilicon or amorphous silicon, may be formed above the semiconductor layer 402 and may be separated therefrom by a gate insulation layer 433a, 433b, which may comprise silicon dioxide, silicon oxynitride material and/or high-k material, as described with regard to FIG. 1c. Offset spacers 434a, 434b, which may be comprised of silicon nitride, silicon dioxide, silicon oxynitride and the like, are provided with an appropriate thickness, which in turn is selected so as to define a desired offset of respective source and drain regions to be formed using the gate electrodes 430a, 430b and the offset spacers 434a, 434b as an implantation mask, as described with regard to FIG. 2c.

The gate electrodes 430a, 430b may be formed on the basis of well-established processes, such as processes based on a replacement technique, a so-called “gate first” technique, i.e., the deposited gate material is maintained in the final gate structure, or a hybrid technique, wherein the gate material of the N-channel or P-channel transistor is replaced, whereas the gate material of the opposite transistor type is maintained. Appropriate materials for the gate electrodes and the gate insulation layer 433a, 433b may be provided, for instance, by oxidation and/or deposition for the gate insulation layer 433a, 433b and by deposition of the material 431a, 431b of the gate electrodes 430a, 430b, followed by advanced lithography and etch techniques in order to appropriately define the lateral dimensions of the gate electrodes 430a, 430b.

In case the gate electrodes 430a, 430b are formed by a polysilicon material in a gate first process, i.e., the polysilicon material is not replaced subsequently, the polysilicon may be pre-doped by performing a corresponding implantation step prior to the gate patterning process. As a different conductivity-type is required for polysilicon material of N-channel and P-channel transistors, corresponding mask techniques may be employed.

For sophisticated applications, the gate length, which also affects the effective channel length, may be in the range of approximately 50 nm and even less for highly advanced semiconductor devices. Next, the offset spacers 434a, 434b may be formed on the basis of conformal deposition techniques and/or oxidation processes, followed by an etch process, wherein the initial layer thickness and the respective etch conditions may substantially determine the width of the offset spacers 434a, 434b.

FIG. 4c schematically illustrates a cross-sectional view of the semiconductor device 400 in a further advanced manufacturing stage in which the active region 402b is covered by a resist mask 407a and an implantation sequence 406a is performed that may comprise a pre-amorphization, a source and drain implantation, extra diffusion engineering implantations and halo implantations to define source and drain regions 427a and halo regions 428a in the active region 402a.

The implantation sequence 406a is performed so as to introduce the required dopant species for defining the source and drain regions 427a, wherein a respective offset to the gate electrode 430a may be obtained by the offset spacers 434a. A corresponding dopant species of a specified conductivity type in accordance with the design of the semiconductor device 400 is implanted. For instance, for a P-channel transistor, the source and drain regions 427a may comprise a P-type dopant species. In an illustrative embodiment, the implantation process 406a is performed to obtain source and drain regions 427a having a depth in the range of approximately 20-50 nm and a mean dopant concentration in the range of approximately 1×10²⁰ to 5×10²⁰ atoms/cm³. As source and drain dopants are also incorporated in the gate electrode, the dopant concentration in the gate electrode may be higher than the dopant concentration in the source and drain regions, when a pre-doped gate electrode material 431a is employed as described with regard to FIG. 2d.

The halo regions 428a may be provided with a dopant profile appropriate for reducing the short channel effects and adjusting the desired threshold voltage of the transistor to be formed in and above the active region 402a. The halo implantation may be performed by means of a tilted implantation performed on the drain side as well as on the source side. In one illustrative embodiment, the halo implantation process 406a is performed with an inclination angle in the range of approximately 20-60° and an implantation energy in the range of approximately 5-30 keV, wherein the applied dose may be in the range of 10¹³ to 10¹⁴ atoms/cm². In a further illustrative embodiment, the process parameters of the halo implantation process 406a are chosen so that the source and the drain side halo regions form an overlap region below the gate electrode. It should be appreciated that other implantation processes may be performed, such as a pre-amorphization implantation, a diffusion engineering implantation and the like, depending on the device requirements.

FIG. 4d schematically illustrates a cross-sectional view of the semiconductor device 400 in a further advanced process stage in which the resist mask 407a (FIG. 4c) is removed from the active region 402b. A resist strip process is performed in order to remove the resist mask 407a, wherein the removal process may be configured as a plasma process based on, e.g., oxygen, and a further reactive component, such as fluorine in the form of carbon hexa fluoride.

A further resist mask 407b is formed covering the active region 402a and exposing the active region 402b during a further implantation sequence 406b performed to provide an appropriate dopant profile in the active region 402b representing a transistor of a different conductivity type, such as a P-channel transistor. The implantation sequence 406b that may again comprise a pre-amorphization, a source and drain implantation, extra diffusion engineering implantations and one or more halo implantation steps to define source and drain regions 427b and halo regions 428b in the active region 402b is performed. As source and drain dopants are also incorporated in the gate electrode, the dopant concentration in the gate electrode may be higher than the dopant concentration in the source and drain regions, when a pre-doped gate electrode material 431b is employed.

The source and drain regions 427b and halo regions 428b in the active region 402b may be formed as set forth with reference FIG. 4c but with the opposite conductivity type. In one illustrative embodiment, the source and drain regions 427b are formed by implanting a P-type species and the halo regions 428b are formed by implanting an N-type species appropriate to form a P-channel transistor in and above the active region 402b. The halo regions 428b may be provided with a dopant profile appropriate for reducing the short channel effects and adjusting the desired threshold voltage of the transistor to be formed in and above the active region 402b as described with regard to the transistor of the opposite conductivity type.

FIG. 4e schematically illustrates a cross-sectional view of the semiconductor device 400 in a further advanced process stage in which the resist mask 407b (FIG. 4d) is removed from the active region 402a. An anneal process 411 may be performed at this manufacturing stage, wherein respective process parameters, that is, the effective anneal temperature and the duration of the process, may be selected such that desired lateral and vertical profiles of the drain and source regions 427a, 427b are obtained and the position of the formed PN junction is defined as previously described. In the anneal process 411 concurrently the implanted ions are electrically activated.

FIG. 4f schematically illustrates a cross-sectional view of the semiconductor device 400 in a further advanced manufacturing stage in which silicide regions 429a, 429b are formed in the drain and source regions 427a, 427b comprising a dopant concentration defined by the drain and source implantations 406a, 406b (FIGS. 4c and 4d). Depending on the employed gate electrode technique, a silicide region may also be formed in the gate electrode. In one illustrative embodiment, a gate replacement approach may be employed, wherein the corresponding gate electrode replacement process is performed after the formation of the silicide regions 427a, 427b.

FIG. 4g schematically illustrates a cross-sectional view of the semiconductor device 400 in a further advanced manufacturing stage in which contact elements 440 may be formed to accomplish the manufacturing process of the semiconductor device 400. Subsequently, a plurality of metallization layers (not shown) may be formed, e.g., on the basis of a well-known copper damascene technique, to form CMOS elements and to provide the desired integrated circuit.

As a result, the present disclosure provides manufacturing techniques for forming semiconductor devices comprising high performance and/or low-power field effect transistors, wherein the threshold voltage of the transistors is adjusted by the halo implantation and the source and drain regions are defined by a single implantation step. Thus, the number of process steps is reduced, whereas the electrical characteristics, such as leakage level, and performance of the transistors are maintained compared to conventional transistors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor device, the method comprising:
providing a substrate comprising a semiconductor layer;
forming a gate electrode structure above an active region formed in said semiconductor layer;
performing an implantation sequence using said gate electrode structure as a mask, wherein source and drain regions and halo regions of a field effect transistor are formed; and
forming silicide regions within said source and drain regions.

2. The method of claim 1, wherein said source and drain regions define an intermediate channel region of said field effect transistor, wherein said source and drain regions and said channel region comprise the same conductivity type.

3. The method of claim 1, wherein said gate electrode structure comprises a spacer element defining a gate length of said field effect transistor.

4. The method of claim 3, wherein said gate length is 50 nm and less.

5. The method of claim 1, wherein said source and drain regions have a depth in the range of approximately 20-50 nm.

6. The method of claim 1, wherein said semiconductor layer is a pre-doped semiconductor layer and isolation regions defining said active region are formed in the pre-doped semiconductor layer.

7. The method of claim 1, wherein:
said semiconductor layer is a pre-doped semiconductor layer comprising an initial doping concentration;
isolation regions defining said active region are formed in said pre-doped semiconductor layer; and
said implantation sequence is performed so that said source and drain regions and said halo regions are formed in said active region comprising said initial doping concentration.

8. The method of claim 1, wherein said halo regions overlap beneath said gate electrode.

9. A method of forming a semiconductor device, the method comprising:
providing a substrate comprising a pre-doped semiconductor layer exhibiting an initial doping concentration;
forming isolation regions defining an active region in said pre-doped semiconductor layer; and
performing an implantation sequence implanting source and drain regions and halo regions of a field effect transistor into said active region exhibiting said initial doping concentration.

10. The method of claim 9, wherein said source and drain regions and said pre-doped semiconductor layer exhibit the same conductivity type.

11. The method of claim 9, further comprising:
forming a gate electrode structure above said active region and using said gate electrode structure as a mask when performing said implantation sequence; and
forming silicide regions within said source and drain regions.

12. The method of claim 9, wherein said halo regions overlap beneath said gate electrode.

13. The method of claim 9, wherein said gate electrode is formed by:
depositing a gate layer stack;
doping said gate layer stack; and
patterning said doped gate layer stack.

14. The method of claim 13, wherein said semiconductor device is a CMOS device comprising a second field effect transistor, wherein the gate layer stack for a gate electrode of said second field effect transistor is doped so that the opposite conductivity type is obtained.

15. A semiconductor device, comprising:
a substrate comprising a semiconductor layer; and
a field effect transistor formed in and above said semiconductor layer, said field effect transistor comprising:
a gate electrode formed above said semiconductor layer; and
source and drain regions formed in said semiconductor layer, wherein the shape of said source and drain regions is defined by a single source and drain implantation.

16. The semiconductor device of claim 15, further comprising a channel region arranged between said source and drain regions of said field effect transistor, wherein said source and drain regions and said channel region comprise the same type of conductivity.

17. The semiconductor device of claim 15, further comprising halo regions, wherein said halo regions overlap beneath said gate electrode.

18. The semiconductor device of claim 15, wherein said gate electrode comprises a semiconductor region comprising a higher doping concentration than said source and drain regions.

19. The semiconductor device of claim 18, wherein said semiconductor device is a CMOS device comprising a second field effect transistor of the opposite conductivity type, wherein said second transistor comprises a gate electrode comprising a semiconductor region exhibiting a higher doping concentration than the source and drain regions of said second field effect transistor.

20. The method of claim 15, wherein said field effect transistor has a gate length of 50 nm and less.
